(19) United States
(12) Patent Application Publication
(10) Pub. No.: US 2016/0336413 A1
(43) Pub. Date: Nov. 17, 2016

(54) RECESS ARRAY DEVICE WITH REDUCED CONTACT RESISTANCE

(71) Applicant: INOTERA MEMORIES, INC., Taoyuan City (TW)

(72) Inventor: Tieh-Chiang Wu, Taoyuan City (TW)

(21) Appl. No.: 14/714,334

(22) Filed: May 17, 2015

(51) Int. Cl. H01L 29/423; H01L 23/535; H01L 27/108

(52) U.S. Cl. CPC H01L 29/4236; H01L 27/10823; H01L 23/535

(57) ABSTRACT

A recess array device includes a semiconductor substrate having a main surface; a recessed trench in the main surface of the semiconductor substrate; a gate electrode disposed at a lower portion of the recessed trench; a liner layer disposed on directly on the gate electrode and being in direct contact with the gate electrode; a gate dielectric layer disposed only between the gate electrode and the semiconductor substrate and between the liner layer and the semiconductor substrate; and an epitaxial silicon layer disposed at an upper portion of the recessed trench.

### BACKGROUND OF THE INVENTION

1. Field of the Invention

The present invention relates generally to semiconductor devices and a method of fabricating the same. More particularly, the present invention relates to a method of fabricating a recessed array device (RAD) with reduced contact resistance.

2. Description of the Prior Art

Recess array device (RAD) integrated in dynamic random access memory (DRAM) is known in the art. To form a RAD, a recess is formed on a surface of a substrate and a gate of a transistor is formed in the recess.

Because the gate is formed in the recess formed in the substrate, the distance between a source and a drain is extended such that the effective channel length increases and the short channel effect decreases.

As the degree of integration of the memory is increased, a pitch of a word line is gradually reduced, resulting in an increase in contact resistance. The increased contact resistance may lead to failure of cell operation due to loss of driving performance.

There is still a need in this industry to provide an improved RAD in order to solve the problems induced by shrinkage of the RAD structure.

### SUMMARY OF THE INVENTION

It is one object of the invention to provide an improved RAD with reduced contact resistance.

According to one aspect of the invention, a recess array device includes a semiconductor substrate having a main surface; a recessed trench in the main surface of the semiconductor substrate; a gate electrode disposed at a lower portion of the recessed trench; a liner layer disposed on directly on the gate electrode and being in direct contact with the gate electrode; a gate dielectric layer disposed only between the gate electrode and the semiconductor substrate and between the liner layer and the semiconductor substrate; and an epitaxial silicon layer disposed at an upper portion of the recessed trench.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The above and other aspects and features of the present invention will become apparent by describing in detail exemplary embodiments thereof with reference to the attached drawings, in which:

FIGS. 1-6 are cross-sectional views depicting one illustrative embodiment of forming a recess array device in accordance with the present invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

In the following description, numerous specific details are given to provide a thorough understanding of the invention. It will, however, be apparent to one skilled in the art that the invention may be practiced without these specific details. Furthermore, some well-known system configurations and process steps are not disclosed in detail, as these should be well-known to those skilled in the art.

Likewise, the drawings showing embodiments of the apparatus are semi-diagrammatic and not to scale and some dimensions are exaggerated in the figures for clarity of presentation. Also, where multiple embodiments are disclosed and described as having some features in common, like or similar features will usually be described with like reference numerals for ease of illustration and description thereof.

With regard to the fabrication of transistors and integrated circuits, the term “major surface” refers to that surface of the semiconductor layer in and about which a plurality of transistors are fabricated, e.g., in a planar process. As used herein, the term “vertical” means substantially orthogonal with respect to the major surface. Typically, the major surface is along a <100> plane of a monocrystalline silicon layer on which the field-effect transistor devices are fabricated.

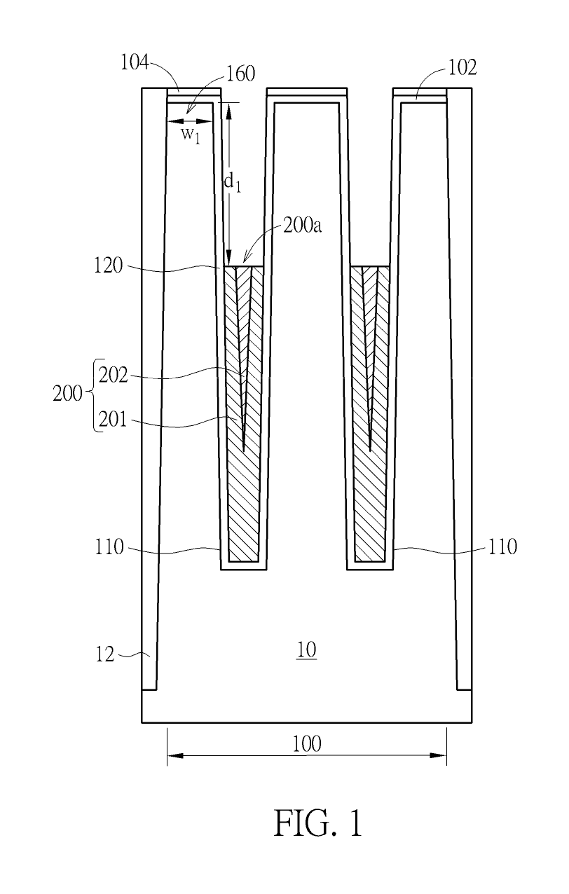

Please refer to FIGS. 1-6, which are cross-sectional views depicting one illustrative embodiment of forming a recess array device (RAD) in accordance with the present invention. First, as shown in FIG. 1, an active area 100 is defined in a semiconductor substrate 10 having thereon a pad oxide layer 102 and a pad nitride layer 104 as an etching mask. Shallow trench isolation (STI) structure 12 is formed in the semiconductor substrate 10 to define the active area 100. The STI structure 12 surrounds the active area 100 and separates the active area 100 from other adjacent active areas.

Subsequently, a lithographic process and an etching process may be carried out to form recessed trenches 110 in the active area 100. The recessed trench 110 maybe a line-shaped trench that interests and traverses the active area 100. It is understood that in some cases, only one recessed trench may be formed in each active area. Thereafter, a thermal oxidation process may be carried out to form a gate dielectric layer 120 such as a silicon dioxide layer on the interior surface of the recessed trenches 110. The gate dielectric layer 120 is formed on the entire sidewall surfaces and bottom surface of each of the recessed trenches 110.

After the formation of the gate dielectric layer 120 in the recessed trenches 110, a gate electrode 200 is formed only at a lower portion of the recessed trenches 110. The gate dielectric layer 120 insulates the gate electrode 200 from the semiconductor substrate 10. The gate electrode 200 has a top surface 200a that has a depth d₁ below a main surface of the semiconductor substrate 10. According to the illustrative embodiment, the gate electrode 200 may comprise a titanium nitride (TiN) layer 201 and a tungsten (W) layer 202, but not limited thereto. It is to be understood that other conductive materials may be employed as the gate electrode.

As previously mentioned, a width w₁ of a contact region 160 between the recessed trench 110 and an edge of the STI structure 12 continuously shrinks as the degree of integration of the memory is increased, which results in a dramatically increase in contact resistance. The present invention addresses this issue.

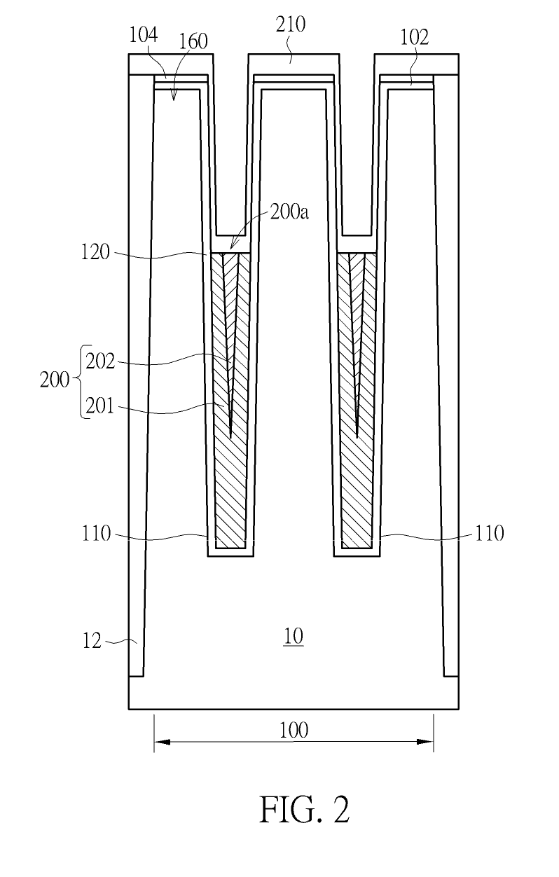

As shown in FIG. 2, a liner layer 210 is then conformally deposited in the recessed trenches 110 and on the pad nitride layer 104. The liner layer 210 conformally covers the gate dielectric layer 120 on the sidewall of the recessed trenches 110 and covers the top surface 200a of the gate electrode 200. The liner layer 210 may be deposited using methods known in the art, for example, chemical vapor deposition (CVD) methods. The liner layer 210 may comprise silicon oxide, but not limited thereto.

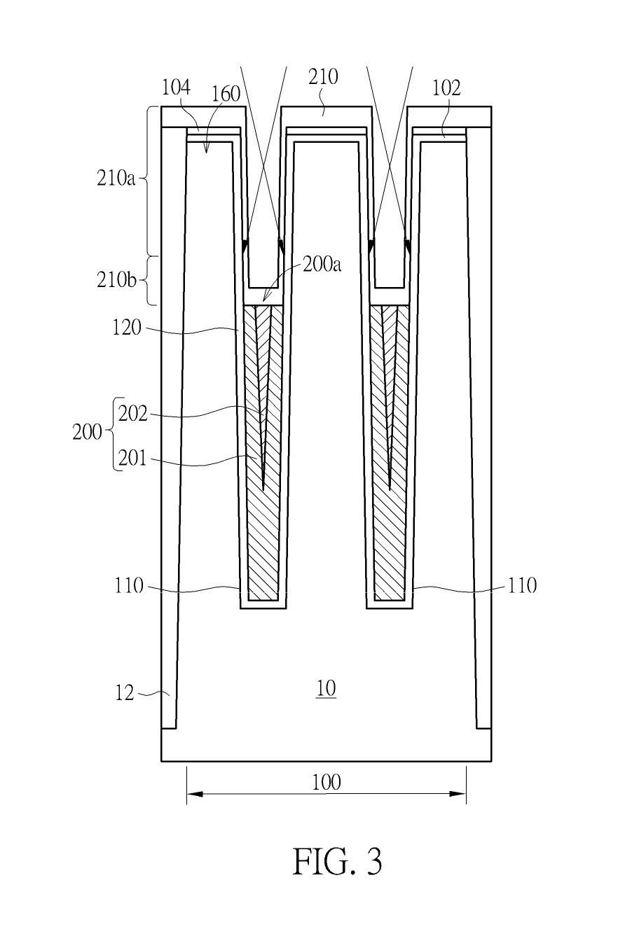

As shown in FIG. 3, after the formation of the liner layer 210, a tilt-angle ion implantation process is performed. By adjusting the implantation angle, the selected ions bombard only the upper portion 210a of the liner layer 210 on the sidewall of the recessed trenches 110. The lower portion 210b of the liner layer 210 within the recessed trenches 110 is substantially not bombarded due to the selected implantation angle.

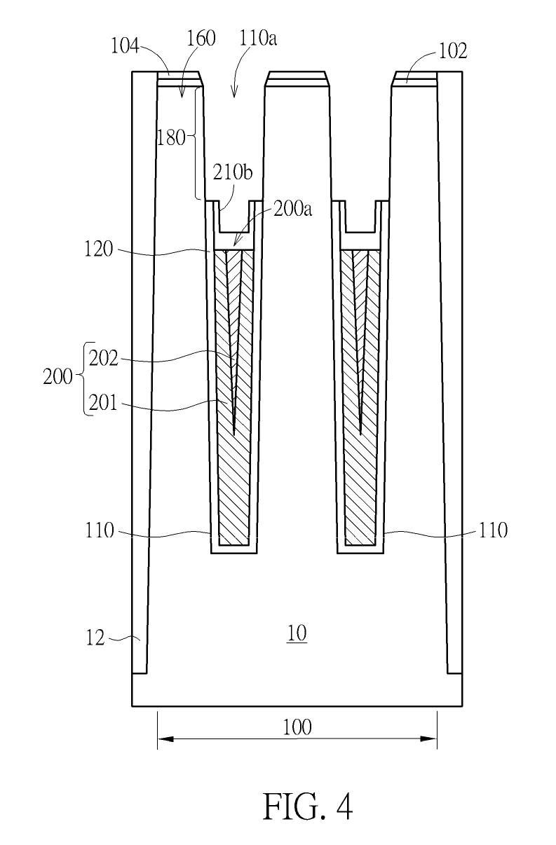

As shown in FIG. 4, the ion-bombarded upper portion 210a of the liner layer 210 is then selectively etched away, leaving the lower portion 210b of the liner layer 210 intact. According to the illustrative embodiment, an upper portion of the gate dielectric layer 120 directly under the upper portion 210a of the liner layer 210 is also removed and the corresponding collar portions 180 of the sidewall surfaces of the recessed trench 110 are exposed. At this point, a widened upper portion of the recessed trench 110 is formed.

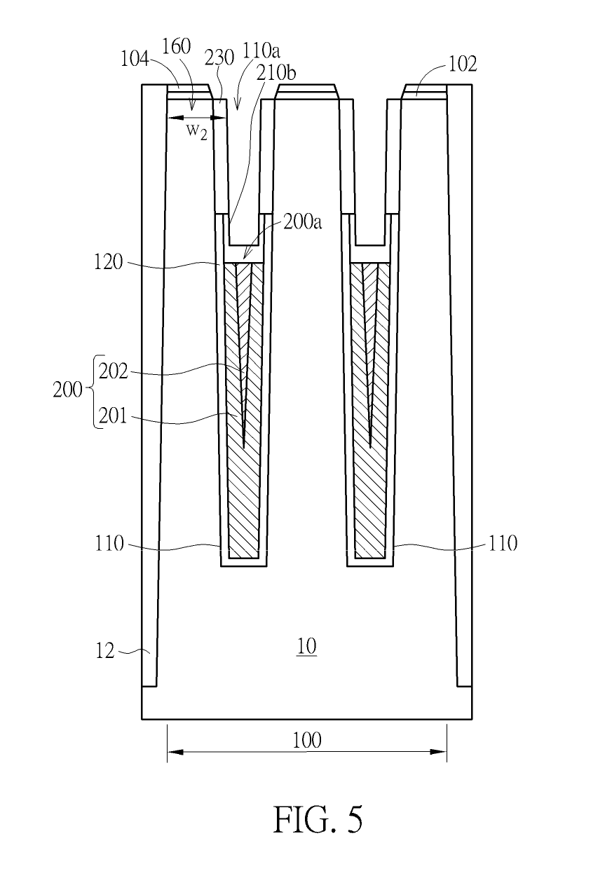

As shown in FIG. 5, after the selective removal of the bombarded upper portion 210a of the liner layer 210, an epitaxial silicon layer 230 is formed on the exposed collar portions 180 of the sidewall surfaces of the recessed trench 110. The epitaxial silicon layer 230 may be formed by methods known in the art, for example, atomic layer deposition (ALD) methods, but not limited thereto. The epitaxial silicon layer 230 is disposed within the recessed trench 110 and directly on an upper sidewall surface of the recessed trench 110.

According to the illustrative embodiment, the epitaxial silicon layer 230 is contiguous with the gate dielectric layer 120. The epitaxial silicon layer 230 is insulated from the gate electrode 200 by the liner layer 210 and the gate dielectric layer 120. The epitaxial silicon layer 230 may be doped with impurities. The epitaxial silicon layer 230 expands the contact region 160 from the width w₁ to the width w₂, thereby reducing the contact resistance.

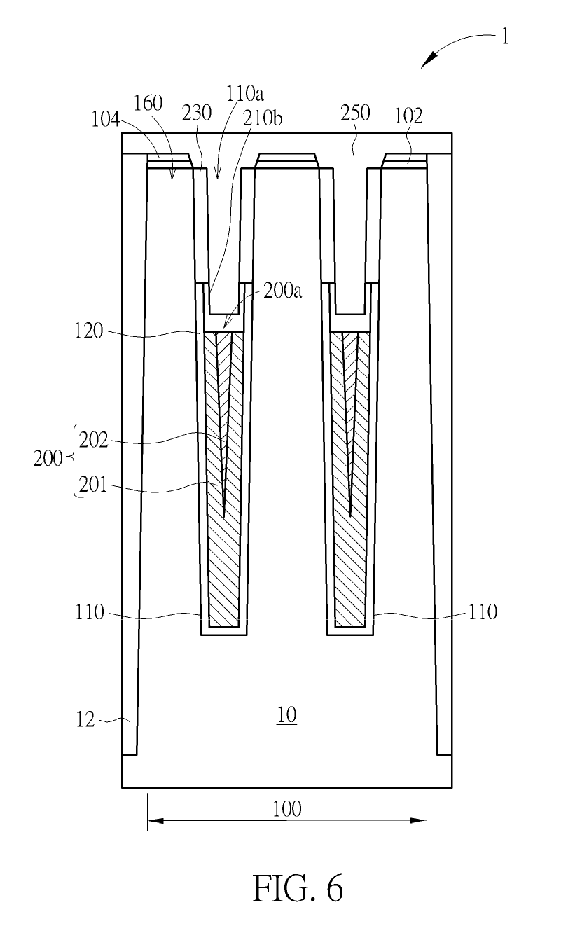

As shown in FIG. 6, subsequently, a dielectric layer 250 may be deposited on the semiconductor substrate 10 and may fill up the remaining space in the recessed trench 110. According to the illustrative embodiment, the dielectric layer 250 may comprise silicon oxide, but not limited thereto. Since the contact region 160 is expanded, the formed RAD 1 has a bottle-shaped sectional profile.

Those skilled in the art will readily observe that numerous modifications and alterations of the device and method may be made while retaining the teachings of the invention. Accordingly, the above disclosure should be construed as limited only by the metes and bounds of the appended claims.

1. A recess array device, comprising:
a semiconductor substrate having a main surface;
a recessed trench in the main surface of the semiconductor substrate, wherein the recessed trench comprises a first sidewall surface and a second sidewall surface directly facing the first sidewall surface;
a gate electrode disposed at a lower portion of the recessed trench, wherein the gate electrode completely fills up the lower portion of the recessed trench, and the gate electrode has a top surface;
a liner layer disposed directly on the gate electrode and being in direct contact with the gate electrode, wherein the liner layer is disposed only above the top surface of the gate electrode;
a gate dielectric layer disposed only between the gate electrode and the semiconductor substrate and between the liner layer and the semiconductor substrate;
a first epitaxial silicon layer disposed on the first sidewall surface at an upper portion of the recessed trench; and
a second epitaxial silicon layer disposed on the second sidewall surface at an upper portion of the recessed trench.

2. The recess array device according to claim 1, wherein the first epitaxial silicon layer is disposed within the recessed trench and directly on the first sidewall surface of the recessed trench, and wherein the second epitaxial silicon layer is disposed within the recessed trench and directly on the second sidewall surface of the recessed trench.

3. The recess array device according to claim 1, wherein the first and second epitaxial silicon layers are contiguous with the gate dielectric layer.

4. The recess array device according to claim 1, wherein the first and second epitaxial silicon layers are insulated from the gate electrode by the liner layer and the gate dielectric layer.

5. The recess array device according to claim 1, wherein the liner layer comprises silicon oxide.

6. The recess array device according to claim 1 further comprising a dielectric layer filling up an upper portion of the recessed trench.
